(19) United States
(12) Patent Application Publication
(10) Pub. No.: US 2019/0097093 A1
(43) Pub. Date: Mar. 28, 2019

(54) LIGHT-EMITTING DEVICE

(71) Applicant: TOYODA GOSEI CO., LTD., Kiyosu-shi (JP)

(72) Inventor: Satomi SEKI, Kiyosu-shi (JP)

(21) Appl. No.: 15/994,726

(22) Filed: May 31, 2018

(30) Foreign Application Priority Data
Sep. 26, 2017 (JP) 2017-185055

(51) Int. Cl. H01L 33/50; C09K 11/70; H01L 33/62

(52) U.S. Cl. CPC H01L 33/502; C09K 11/70; F21Y 2115/10; H01L 33/505; H01L 33/62

(57) ABSTRACT

A light-emitting device includes a light-emitting element that emits light with a peak wavelength in a range of 380 nm to 460 nm, and a phosphor group that includes plural kinds of phosphors excited by the light emitted from the light-emitting element and has a continuous emission spectrum in a wavelength range of 400 nm to 780 nm. The phosphor group includes a phosphor having a peak wavelength in a range of 720 nm±5%.

### BACKGROUND OF INVENTION

### 1. Field of Invention

The invention relates to a light-emitting device.

### 2. Related Art

In recent years, attempt to mimic electric bulb color, light of halogen lamp and natural sunlight by using LEDs (Light Emitting Diode) has been made in many places, and various phosphors have been developed to obtain light with high color rendering properties.

For example, an LED module which emits light exhibiting a continuous emission spectrum distribution across a wavelength range of 380 nm to 780 nm is known to mimic how filament of incandescent lamp emits light or to mimic its color (see, e.g., JP 2016/76652 A). In the LED module disclosed in JP 2016/76652 A, at least four types of phosphors, which are blue, green, yellow and red phosphors, are used.

Meanwhile, a light-emitting device with a general color rendering index Ra of more than 85 and a special color rendering index R9 (red) of more than 50 is known (see, e.g., JP 2016/111190 A). In the light-emitting device disclosed in JP 2016/111190 A, four types of phosphors with emission peaks in different wavelength ranges are used.

### SUMMARY OF INVENTION

In the known light-emitting devices including the devices disclosed in JP 2016/76652 A and JP 2016/111190 A, however, since a phosphor with a peak wavelength at around 660 nm is used as a red phosphor forming the red region of the emission spectrum, the emission spectrum of the device is very different from the spectrum of sunlight or halogen light particularly in a deep red region at not less than 700 nm. Therefore, lack of color in the deep red region is noticeable when trying to mimic sunlight or halogen light.

It is an object of the invention to provide a light-emitting device whose emission spectrum intensity in the deep red region is relatively increased so as to suppress a decrease in the color rendering properties.

According to one embodiment of the invention, a light-emitting device defined below by [1] to [8] is provided.

[1] A light-emitting device, comprising:

a light-emitting element that emits light with a peak wavelength in a range of 380 nm to 460 nm; and

a phosphor group that comprises a plurality of kinds of phosphors excited by the light emitted from the light-emitting element and has a continuous emission spectrum in a wavelength range of 400 nm to 780 nm, wherein the phosphor group comprises a phosphor having a peak wavelength in a range of 720 nm±5%.

[2] The light-emitting device according to [1], wherein said phosphor having the peak wavelength in the range of 720 nm±5% comprises an oxide that includes Gd and Ga.

[3] The light-emitting device according to [2], wherein the oxide comprises a Cr-activated Gd₃Ga₅O₁₂.

[4] The light-emitting device according to any one of [1] to [3], wherein a color rendering index Rf is not less than 95 when using light with a color temperature of 3000K as a reference light, and a difference from 100 of a color rendering index Rg is not more than 5 when using light with a color temperature of 3000K as a reference light.

[5] The light-emitting device according to any one of [1] to [4], wherein the phosphor group comprises two types of alkaline earth halophosphate phosphors, a β-sialon phosphor and a CASON phosphor.

[6] The light-emitting device according to any one of [1] to [3], wherein a color rendering index Rf is not less than 95 when using light with a color temperature of 6500K as a reference light, and a difference from 100 of a color rendering index Rg is not more than 5 when using light with a color temperature of 6500K as a reference light.

[7] The light-emitting device according to any one of [1] to [3] and [6], wherein a special color rendering index R9 is not less than 96.8 when using light with a color temperature of 6500K as a reference light.

[8] The light-emitting device according to any one of [1] to [3], [6] and [7], wherein the phosphor group comprises two types of alkaline earth halophosphate phosphors, a β-sialon phosphor, a Ca solid solution α-sialon phosphor and a CASON phosphor.

### Effects of Invention

According to one embodiment of the invention, a light-emitting device can be provided whose emission spectrum intensity in the deep red region is relatively increased so as to suppress a decrease in the color rendering properties.

### BRIEF DESCRIPTION OF DRAWINGS

Next, the present invention will be explained in more detail in conjunction with appended drawings, wherein:

FIG. 1 is a vertical cross-sectional view showing a light-emitting device in an embodiment;

FIG. 2 is a graph showing emission spectra of light-emitting devices when a combination of phosphors and a ratio between concentrations thereof are adjusted so that the emission spectrum has a shape close to that of evening sunlight with a color temperature of 3000K; and

FIG. 3 is a graph showing emission spectra of light-emitting devices when a combination of phosphors and a ratio between concentrations thereof are adjusted so that the emission spectrum has a shape close to that of morning to afternoon sunlight with a color temperature of 6500K.

### DESCRIPTION OF EMBODIMENTS

### Embodiment

Configuration of Light-Emitting Device

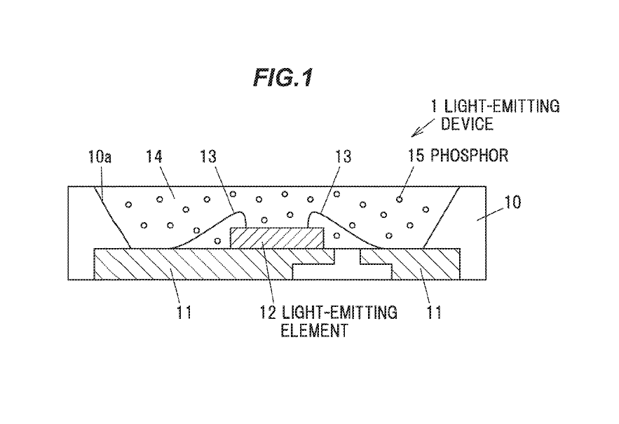

FIG. 1 is a vertical cross-sectional view showing a light-emitting device 1 in an embodiment. The light-emitting device 1 has a case 10 having a recessed portion 10a, a lead frame 11 included in the case 10 so as to be exposed on the bottom of the recessed portion 10a, a light-emitting element 12 mounted on the lead frame 11, bonding wires 13 electrically connecting the lead frame 11 to electrodes of the light-emitting element 12, a sealing resin 14 filled in the recessed portion 10a to seal the light-emitting element 12, and a particular phosphor 15 contained in the sealing resin 14.

The case 10 is formed by injection molding or transfer molding using, e.g., a thermoplastic resin such as polyphthalamide resin, LCP (Liquid Crystal Polymer) or PCT (Polycyclohexylene Dimethylene Terephalate), or a thermosetting resin such as silicone resin, modified silicone resin, epoxy resin or modified epoxy resin. The case 10 may contain light-reflecting particles of titanium dioxide, etc., to improve light reflectance.

For example, the entire lead frame 11 or the surface thereof is formed of a conductive material such as Ag, Cu or Al.

The light-emitting element 12 is typically an LED element or a laser diode element. The light-emitting element 12 is a face-up type element connected to the lead frame 11 via the bonding wires 13 in the example shown in FIG. 1, but may be a face-down type element or may be connected to the lead frame via a connecting member other than bonding wires, e.g., via conductive bumps.

The light-emitting element 12 emits light with a peak wavelength in a range from 380 nm to 460 nm (the range of not less than 380 nm and not more than 460 nm). Since phosphors included in the phosphor 15 (described later) can be efficiently excited by light with a wavelength of not more than 460 nm, the peak wavelength of the light emitted from the light-emitting element 12 is preferably not more than 460 nm.

On the other hand, if the peak wavelength of the light emitted from the light-emitting element 12 is too short, the emission spectrum of the light-emitting device 1 is less likely to be close to that of sunlight due to a too large valley between the peak of the emission spectrum of the light-emitting element 12 and that of the phosphor 15. Therefore, the peak wavelength of the light emitted from the light-emitting element 12 is preferably not less than 380 nm.

The sealing resin 14 is formed of, e.g., a resin material such as silicone-based resin or epoxy-based resin.

The phosphor 15 is a phosphor which is excited by light emitted from the light-emitting element 12 and emits fluorescence. The phosphor 15 is a phosphor group consisting of plural types of phosphors, has a continuous emission spectrum (never having zero intensity) across at least a wavelength range of 400 nm to 780 nm, and includes a phosphor emitting deep red light (hereinafter, referred to as “deep red phosphor”) having a peak wavelength in a range of 720 nm±5% so that the light-emitting device 1 can have an emission spectrum close to that of sunlight.

The deep red phosphor is formed of an oxide containing Gd and Ga, and is, e.g., a Cr-activated Gd₃Ga₅O₁₂ (Gd₃Ga₅O₁₂: Cr³⁺), etc. The deep red phosphor can relatively increase intensity in the deep red region of the emission spectrum of the light-emitting device 1, thereby preventing the emission spectrum in the deep red region from being different from the spectrum of sunlight or halogen light.

In addition, it is preferable that the phosphor 15 also include at least one type of blue phosphor having a peak wavelength in a range of 445 nm to 490 nm, at least one type of yellow-green phosphor having a peak wavelength in a range of 491 nm to 600 nm, and at least one type of red phosphor having a peak wavelength in a range of 601 nm to 670 nm so that the light-emitting device 1 has a continuous emission spectrum across a wavelength range of 400 nm to 780 nm.

The usable blue phosphor having a peak wavelength in a range of 445 nm to 490 nm is, e.g., alkaline earth halophosphate phosphor. The main compositions of the alkaline earth halophosphate phosphor are shown in Table 1 below.

TABLE 1

| Phosphor | Main composition |
|---|---|
| Alkaline earth halophosphate phosphor | (Ba,Sr,Ca,Mg)₅(PO₄)₃Cl:Eu²⁺ |
| | (Ba,Sr,Ca,Mg)₁₀(PO₄)₆Cl₂:Eu²⁺ |

The emission spectrum of the earth halophosphate phosphor can be changed by changing concentrations of Eu as an activator or Ba, Sr, Ca, Mg as alkaline earth metals.

The usable yellow-green phosphors having a peak wavelength in a range of 491 nm to 600 nm are, e.g., Ca solid solution α-sialon phosphor, β-sialon phosphor, silicate phosphor, nitride phosphor, LSN phosphor, YAG phosphor and LuAG phosphor. The main compositions of these phosphors are shown in Table 2 below.

TABLE 2

| Phosphor | Main composition |
|---|---|
| Ca solid solution α-sialon phosphor | Ca—Si₁₂₋₍ₘ₊ₙ₎Alₘ₊ₙOₙN₁₆₋ₙ:Eu²⁺ |
| β-sialon phosphor | Si_{6-z}Al_{z}O_{z}N_{8-z}:Eu²⁺ |
| Silicate phosphor | (Ca,Sr,Ba)₃SiO₅:Eu²⁺ |
| | (Ba,Sr,Ca)₂SiO₄:Eu²⁺ |
| Nitride phosphor | (Ca,Sr,Ba)₂Si₅N₈:Eu²⁺ |
| LSN phosphor | (La,Ca)₃Si₆N₁₁:Ce³⁺ |
| YAG phosphor | (Y,Gd)₃(Al,Ga)₅O₁₂:Ce³⁺ |
| LuAG phosphor | Lu₃(Al,Ga)₅O₁₂:Ce³⁺ |

The emission spectra of the YAG phosphor and the LuAG phosphor can be changed by changing concentrations of Ce as an activator or Gd, Ga.

The usable red phosphors having a peak wavelength in a range of 601 nm to 670 nm are, e.g., CASN phosphor, SCASN phosphor and CASON phosphor. The main compositions of these phosphors are shown in Table 3 below.

TABLE 3

| Phosphor | Main composition |
|---|---|
| CASN phosphor | CaAlSiN₃:Eu²⁺ |
| SCASN phosphor | (Sr,Ca)AlSiN₃:Eu²⁺ |
| CASON phosphor | CaAlSi(O,N)₃:Eu²⁺ |

The emission spectra of the CASN phosphor, the SCASN phosphor and the CASON phosphor can be changed by changing concentrations of Eu as an activator or Sr, Ca as alkaline earth metals.

A combination of the phosphors constituting the phosphor 15 and a ratio between concentrations thereof are adjusted so that the emission spectrum of the light-emitting device 1 is close to that of sunlight, e.g., so that color rendering indices Rf, Rg, a general color rendering index Ra and a special color rendering index Ri (i=9 to 15) are close to 100 when using sunlight as a reference light.

The general color rendering index Ra and the special color rendering index Ri (i=9 to 15) are parameters to numerically evaluate color rendering properties used in Method of specifying color rendering properties of light sources (JIS Z 8726:1990) specified by Japanese Industrial Standard. The closer the numerical values are to 100, the closer to the reference light (sunlight, etc.).

Meanwhile, the color rendering indices Rf and Rg are color rendering indices used in TM-30-15 which is a new method for evaluating light source's color rendering properties defined by Illuminating Engineering Society of North America (IES).

Rf is a parameter indicating fidelity of color and is obtained by a test based on comparison to 99 colors. Thus, evaluation of the fidelity of color by Rf is more accurate than by the general color rendering index Ra. The maximum Rf is 100. The closer the Rf is to 100, the closer the color of the test light is to the color of the reference light (sunlight, etc.).

Rg is a parameter indicating color clearness and is not used in the conventional evaluation methods. The closer the Rg is to 100, the closer the color clearness of the test light is to the reference light (sunlight, etc.). The value of Rg can be smaller or greater than 100.

The form of the phosphor 15 provided in the light-emitting device 1 is not specifically limited. For example, the phosphor 15 may be dispersed in the sealing resin 14 or may be settled on the bottom of the sealing resin 14. Furthermore, the phosphor 15 may be contained in a phosphor layer applied on the light-emitting element.

In addition, the configuration of the light-emitting device 1 is not limited that shown in the present embodiment as long as the light-emitting element 12 and the phosphor 15 are provided. For example, the light-emitting device 1 may be a surface-mount device (SMD) as shown in FIG. 1 or may be a Chip-On-Board (COB) device.

### Effects of the Embodiment

According to the embodiment, it is possible to provide the light-emitting device 1 having an emission spectrum in which intensity in the deep red region is relatively increased to solve the problem of lack of color in the deep red region while suppressing a decrease in color rendering properties.

The light-emitting device 1 in the embodiment, which has an emission spectrum closer to that of sunlight than conventional devices, has high color rendering properties and can reveal the true color in indoor environment, hence, suitable for lighting up, e.g., food or cloths. In addition, the light-emitting device 1 is suitable for color test and may be used for evaluating, e.g., paint color of vehicle, etc.

### Example 1

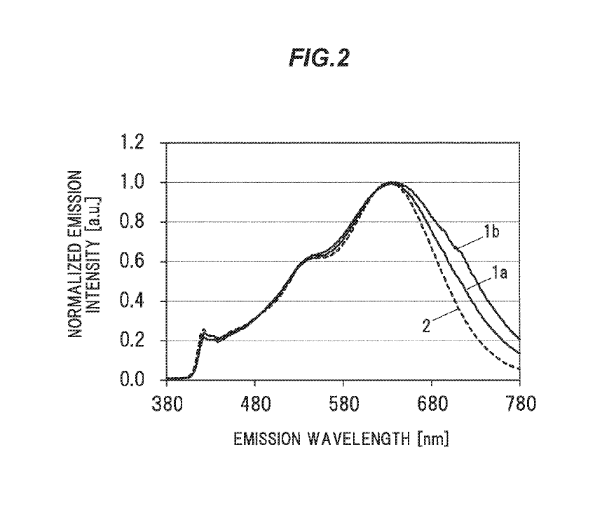

FIG. 2 is a graph showing emission spectra of the light-emitting devices 1 (1a, 1b) and a light-emitting device 2 when a combination of the phosphors constituting the phosphor 15 and a ratio between concentrations thereof are adjusted so that the emission spectrum has a shape close to that of evening sunlight with a color temperature of 3000K. Each emission spectrum shown in FIG. 2 is normalized so that the respective spectral radiant flux (W/nm) has the maximum value of 1.

The light-emitting device 2 is a light-emitting device provided as Comparative Example and not including a deep red phosphor in the phosphor 15, and the configuration of the light-emitting device 2 excluding the phosphor 15 is the same as the light-emitting devices 1 (1a, 1b).

The light-emitting devices 1 (1a, 1b) in FIG. 2 have the phosphor 15 consisting of two types of alkaline earth halophosphate phosphors as blue phosphors, a β-sialon phosphor as a yellow-green phosphor, a CASON phosphor as a red phosphor, and a Cr-activated Gd₃Ga₅O₁₂ as a deep red phosphor. The phosphor 15 of the light-emitting device 2 includes these phosphors except the Cr-activated Gd₃Ga₅O₁₂ which is included in the phosphor 15 of the light-emitting devices 1 (1a, 1b).

Table 4 below shows characteristics of the above-listed phosphors constituting the phosphors 15 of the light-emitting devices 1 (1a, 1b) and the light-emitting device 2 in FIG. 2.

TABLE 4

| | | Emission | | | |
|---|---|---|---|---|---|
| | Excitation | peak | | | |
| | wavelength | wavelength | HMFW | Chromaticity | |
| | (nm) | (nm) | (nm) | x | y |
| Alkaline earth | 405 | 455 | 59 | 0.165 | 0.177 |
| halophosphate | | | | | |
| phosphor | | | | | |
| Alkaline earth | 405 | 482 | 83 | 0.176 | 0.291 |
| halophosphate | | | | | |
| phosphor | | | | | |
| β-sialon phosphor | 405 | 544 | 55 | 0.364 | 0.615 |
| CASON phosphor | 405 | 639 | 125 | 0.576 | 0.417 |
| Cr-activated | 450 | 739 | 90 | 0.489 | 0.517 |
| Gd₃Ga₅O₁₂ | | | | | |

Table 5 below shows a ratio between concentrations of the phosphors constituting the phosphors 15 of the light-emitting devices 1 (1a, 1b) and the light-emitting device 2 in FIG. 2. In Table 5, “Phosphor concentration” is a value (wt %) of the ratio of the mass of the phosphors 15 to the total mass of the sealing resin 14 formed of a methyl-based silicone and the phosphors 15.

In addition, “Phosphor concentration ratio” in Table 5 is a value (wt %) of the ratio of the mass of each phosphor to the mass of the phosphors 15 (the all phosphors), and “SCA1”, “SCA2”, “β”, “CASON” and “GGG” respectively refer to an alkaline earth halophosphate phosphor (peak wavelength of 455 nm), another alkaline earth halophosphate phosphor (peak wavelength of 482 nm), a β-sialon phosphor, a CASON phosphor and a Cr-activated Gd₃Ga₅O₁₂.

TABLE 5

| | Phosphor | | | | | |
|---|---|---|---|---|---|---|
| | concentration | Phosphor concentration ratio (wt %) | | | | |
| | (wt %) | SCA1 | SCA2 | β | CASON | GGG |
| Light-emitting | 55 | 31.6 | 47.4 | 3.8 | 17.2 | 0 |
| device 2 | | | | | | |
| Light-emitting | 56.7 | 29.5 | 44.2 | 3.5 | 16.0 | 7.5 |
| device 1a | | | | | | |
| Light-emitting | 58.6 | 27.4 | 41.1 | 2.4 | 15.3 | 13.8 |
| device 1b | | | | | | |

Table 6 below shows the color rendering indices Rf, Rg, the color rendering indices R1 to R8, the general color rendering index Ra and the special color rendering index Ri (i=9 to 15) of the light-emitting devices 1 (1a, 1b) and the light-emitting device 2 in FIG. 2 when evening sunlight with a color temperature of 3000K is used as a reference light. The general color rendering index Ra here is an average of the color rendering indices R1 to R8.

TABLE 6

| | Light-emitting | Light-emitting | Light-emitting |
|---|---|---|---|
| | device 2 | device 1a | device 1b |
| Rf | 96.7 | 97.4 | 98.2 |
| Rg | 101.2 | 100.7 | 99.6 |
| Ra | 97.9 | 98.3 | 98.6 |
| R1 | 98.5 | 99.3 | 99.8 |
| R2 | 99.8 | 99.5 | 98.8 |
| R3 | 96.0 | 96.3 | 96.4 |
| R4 | 96.6 | 97.4 | 98.3 |
| R5 | 98.4 | 99.1 | 99.8 |
| R6 | 98.6 | 99.4 | 99.5 |
| R7 | 98.5 | 98.8 | 99.5 |
| R8 | 97.1 | 97.0 | 97.0 |
| R9 | 92.0 | 91.4 | 90.7 |
| R10 | 97.8 | 97.1 | 96.1 |
| R11 | 94.9 | 96.0 | 97.0 |
| R12 | 97.2 | 97.7 | 97.0 |
| R13 | 98.6 | 99.5 | 99.6 |
| R14 | 96.7 | 97.0 | 97.3 |
| R15 | 99.0 | 98.6 | 98.0 |

As shown in Table 6, the color rendering indices of the light-emitting devices 1 (1a, 1b) are equivalent to or better than the color rendering indices of the light-emitting device 2. This shows that when using evening sunlight with a color temperature of 3000K as a reference light, a decrease in color rendering properties of the emission spectrum of the light-emitting device is suppressed even when a deep red phosphor is added to the phosphor 15 to increase a red component.

For example, according to Table 6, the color rendering indices of the light-emitting devices 1 when using evening sunlight with a color temperature of 3000K as a reference light can be such that Rf is not less than 97.4, a difference from 100 of Rg is not more than 0.7, and Ra is not less than 98.3. Note that, in comparison with evening sunlight with a color temperature of 3000K, the desirable Rf is not less than 95 and the desirable difference from 100 of Rg is not more than 5.

In addition, as shown in FIG. 2, intensity in the red region of the emission spectrum, particularly in the deep red region at not less than 700 nm, is stronger in the light-emitting devices 1 (1a, 1b) than in the light-emitting device 2. That is, by including a deep red phosphor in the phosphor 15 and appropriately adjusting the phosphor concentration ratio, it is possible to relatively increase intensity in the deep red region of the emission spectrum while suppressing a decrease in color rendering properties.

In case of the light-emitting device 2, simple addition of a Cr-activated Gd₃Ga₅O₁₂ to the phosphor 15 causes a relative decrease in a blue component and a resulting decrease in color rendering properties. In such a case, a mixture ratio of phosphors needs to be adjusted so that the color rendering index is improved, in the same manner as the light-emitting devices 1 (1a, 1b).

### Example 2

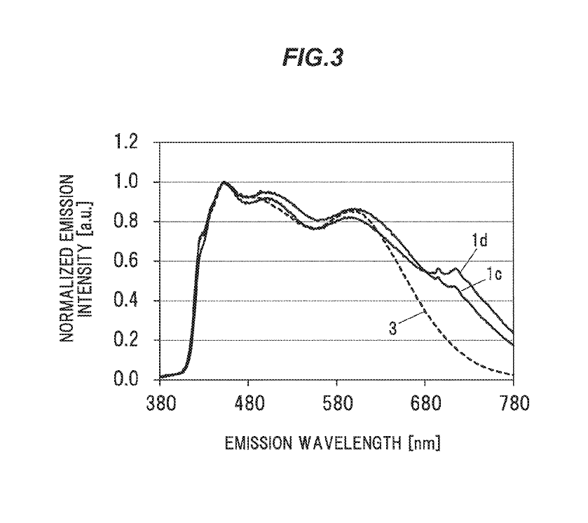

FIG. 3 is a graph showing emission spectra of the light-emitting devices 1 (1c, 1d) and a light-emitting device 3 when a combination of the phosphors constituting the phosphor 15 and a ratio between concentrations thereof are adjusted so that the emission spectrum has a shape close to that of morning to afternoon sunlight with a color temperature of 6500K. Each emission spectrum shown in FIG. 3 is normalized so that the respective spectral radiant flux (W/nm) has the maximum value of 1.

The light-emitting device 3 is a light-emitting device provided as Comparative Example and not including a deep red phosphor in the phosphor 15, and the configuration of the light-emitting device 3 excluding the phosphor 15 is the same as the light-emitting devices 1 (1c, 1d).

The light-emitting devices 1 (1c, 1d) in FIG. 3 have the phosphor 15 consisting of two types of alkaline earth halophosphate phosphors as blue phosphors, a β-sialon phosphor and a Ca solid solution α-sialon phosphor as yellow-green phosphors, a CASON phosphor as a red phosphor, and a Cr-activated Gd₃Ga₅O₁₂ as a deep red phosphor. The phosphor 15 of the light-emitting device 3 includes these phosphors except the Cr-activated Gd₃Ga₅O₁₂ which is included in the phosphor 15 of the light-emitting devices 1 (1c, 1d).

Table 7 below shows characteristics of the Ca solid solution α-sialon phosphor constituting the phosphors 15 of the light-emitting devices 1 (1c, 1d) and the light-emitting device 3 in FIG. 3. The characteristics of the other phosphors are the same as those shown in Table 4.

TABLE 7

| | | Emission | | | |
|---|---|---|---|---|---|
| | Excitation | peak | | | |
| | wavelength | wavelength | HMFW | Chromaticity | |
| | (nm) | (nm) | (nm) | x | y |
| Ca solid solution | 405 | 594 | 84 | 0.546 | 0.444 |
| α-sialon phosphor | | | | | |

Table 8 below shows a ratio between concentrations of the phosphors constituting the phosphors 15 of the light-emitting devices 1 (1c, 1d) and the light-emitting device 3 in FIG. 3. In Table 8, “Phosphor concentration” is a value (wt %) of the ratio of the mass of the phosphors 15 to the total mass of the sealing resin 14 formed of a methyl-based silicone and the phosphors 15.

In addition, “Phosphor concentration ratio” in Table 8 is a value (wt %) of the ratio of the mass of each phosphor to the mass of the phosphors 15 (the all phosphors), and “α” refers to the Ca solid solution α-sialon phosphor. The abbreviated names of the other phosphors are the same as shown in Table 5.

TABLE 8

| | Phosphor | | | | | | |
|---|---|---|---|---|---|---|---|
| | concentration | Phosphor concentration ratio (wt %) | | | | | |
| | (wt %) | SCA1 | SCA2 | β | α | CASON | GGG |
| Light- | 33 | 63.2 | 29.8 | 0.9 | 2.1 | 4.0 | 0 |
| emitting | | | | | | | |
| device 3 | | | | | | | |
| Light- | 31.9 | 58.4 | 17.5 | 0.7 | 1.2 | 5.3 | 16.9 |
| emitting | | | | | | | |
| device 1c | | | | | | | |
| Light- | 36.2 | 65.5 | 7.3 | 0.4 | 1.2 | 4.7 | 20.8 |
| emitting | | | | | | | |
| device 1d | | | | | | | |

Table 9 below shows the color rendering indices Rf, Rg, the color rendering indices R1 to R8, the general color rendering index Ra and the special color rendering index Ri (i=9 to 15) of the light-emitting devices 1 (1c, 1d) and the light-emitting device 3 in FIG. 3 when morning to afternoon sunlight with a color temperature of 6500K is used as a reference light.

TABLE 9

| | Light-emitting | Light-emitting | Light-emitting |
|---|---|---|---|
| | device 3 | device 1c | device 1d |
| Rf | 94.7 | 96.2 | 95.4 |
| Rg | 99.6 | 100.7 | 100.3 |
| Ra | 94.8 | 96.3 | 96.1 |
| R1 | 96.6 | 95.5 | 96.4 |
| R2 | 95.6 | 96.1 | 96.0 |
| R3 | 94.1 | 96.4 | 94.6 |
| R4 | 97.2 | 96.0 | 97.2 |
| R5 | 96.2 | 95.6 | 96.6 |
| R6 | 92.7 | 94.6 | 94.6 |
| R7 | 93.9 | 97.8 | 96.4 |
| R8 | 92.2 | 98.9 | 97.1 |
| R9 | 83.6 | 97.8 | 96.8 |
| R10 | 90.0 | 90.9 | 89.9 |
| R11 | 95.0 | 93.3 | 95.1 |
| R12 | 91.3 | 93.5 | 93.6 |
| R13 | 96.0 | 95.1 | 95.7 |
| R14 | 96.9 | 97.9 | 96.8 |
| R15 | 99.3 | 96.9 | 98.2 |

As shown in Table 9, the color rendering indices of the light-emitting devices 1 (1c, 1d) are equivalent to or better than the color rendering indices of the light-emitting device 3. This shows that when using morning to afternoon sunlight with a color temperature of 6500K as a reference light, a decrease in color rendering properties of the emission spectrum of the light-emitting device is suppressed even when a deep red phosphor is added to the phosphor 15 to increase a red component.

For example, according to Table 9, the color rendering indices of the light-emitting devices 1 when using morning to afternoon sunlight with a color temperature of 6500K as a reference light can be such that Rf is not less than 95.4, a difference from 100 of Rg is not more than 0.7, Ra is not less than 96.1, and R9 (red) is not less than 96.8. Note that, in comparison with morning to afternoon sunlight with a color temperature of 6500K, the desirable Rf is not less than 95 and the desirable difference from 100 of Rg is not more than 5.

In addition, as shown in FIG. 3, intensity in the red region of the emission spectrum, particularly in the deep red region at not less than 700 nm, is stronger in the light-emitting devices 1 (1c, 1d) than in the light-emitting device 3. That is, by including a deep red phosphor in the phosphor 15 and appropriately adjusting the phosphor concentration ratio, it is possible to relatively increase intensity in the deep red region of the emission spectrum while suppressing a decrease in color rendering properties.

In case of the light-emitting device 3, simple addition of a Cr-activated Gd₃Ga₅O₁₂ to the phosphor 15 causes a relative decrease in a blue component and a resulting decrease in color rendering properties. In such a case, a mixture ratio of phosphors needs to be adjusted so that the color rendering index is improved, in the same manner as the light-emitting devices 1 (1c, 1d).

Although the embodiment and Examples of the invention have been described, the invention is not intended to be limited to the embodiment and Examples, and the various kinds of modifications can be implemented without departing from the gist of the invention.

For example, although evening sunlight with a color temperature of 3000K and morning to afternoon sunlight with a color temperature of 6500K are used as the reference in Examples, light to be reference is not limited thereto. For example, using, e.g., sunlight with a given color temperature in a range of 2000 to 9000K, or light of halogen lamp, as a reference, intensity in the deep red region of the emission spectrum can be relatively increased while suppressing a decrease in color rendering properties.

In addition, the invention according to claims is not to be limited to the embodiment and Examples. Further, it should be noted that all combinations of the features described in the embodiment and Examples are not necessary to solve the problem of the invention.

1. A light-emitting device, comprising:
a light-emitting element that emits light with a peak wavelength in a range of 380 nm to 460 nm; and
a phosphor group that comprises a plurality of kinds of phosphors excited by the light emitted from the light-emitting element and has a continuous emission spectrum in a wavelength range of 400 nm to 780 nm,
wherein the phosphor group comprises a phosphor having a peak wavelength in a range of 720 nm±5%.

2. The light-emitting device according to claim 1, wherein said phosphor having the peak wavelength in the range of 720 nm±5% comprises an oxide that includes Gd and Ga.

3. The light-emitting device according to claim 2, wherein the oxide comprises a Cr-activated Gd₃Ga₅O₁₂.

4. The light-emitting device according to claim 1, wherein a color rendering index Rf is not less than 95 when using light with a color temperature of 3000K as a reference light, and a difference from 100 of a color rendering index Rg is not more than 5 when using light with a color temperature of 3000K as a reference light.

5. The light-emitting device according to claim 1, wherein the phosphor group comprises two types of alkaline earth halophosphate phosphors, a β-sialon phosphor and a CASON phosphor.

6. The light-emitting device according to claim 1, wherein a color rendering index Rf is not less than 95 when using light with a color temperature of 6500K as a reference light, and a difference from 100 of a color rendering index Rg is not more than 5 when using light with a color temperature of 6500K as a reference light.

7. The light-emitting device according to claim 1, wherein a special color rendering index R9 is not less than 96.8 when using light with a color temperature of 6500K as a reference light.

8. The light-emitting device according to claim 1, wherein the phosphor group comprises two types of alkaline earth halophosphate phosphors, a β-sialon phosphor, a Ca solid solution α-sialon phosphor and a CASON phosphor.
